(19) United States
(12) Patent Application Publication
(10) Pub. No.: US 2026/0164821 A1
(43) Pub. Date: Jun. 11, 2026

(54) PHOTODETECTION DEVICE AND ELECTRONIC DEVICE

(71) Applicant: SONY SEMICONDUCTOR SOLUTIONS CORPORATION, KANAGAWA (JP)

(72) Inventor: SHUNSUKE MARUYAMA, KANAGAWA (JP)

(21) Appl. No.: 18/721,729

(22) PCT Filed: Dec. 28, 2021
(86) PCT No.: PCT/JP2021/048832

§ 371 Date: Jun. 19, 2024

(51) Int. Cl. H10F 39/00

(52) U.S. Cl. CPC H10F 39/8033; H10F 39/805

(57) ABSTRACT

Provided are a photodetection device and an electronic device capable of suppressing generation of crystal defects while maintaining visible light sensitivity. A photodetection device includes a pixel region in which a plurality of pixels is arranged in a matrix, and the plurality of pixels is capable of generating electric signals in accordance with infrared light and visible light incident from outside. The pixel region includes a light transmitting layer and a photoelectric conversion layer. The light transmitting layer includes a first compound semiconductor and transmits incident infrared light. The photoelectric conversion layer is laminated on a surface of the light transmitting layer on a side opposite to a light incident surface, includes a second compound semiconductor different from the first compound semiconductor, and photoelectrically converts infrared light transmitted through the light transmitting layer. The light transmitting layer includes a first semiconductor layer provided on the light incident surface side and having a thickness allowing transmission of visible light, and a second semiconductor layer laminated on a surface of the first semiconductor layer on a side opposite to the light incident surface and configured to photoelectrically convert the visible light transmitted through the first semiconductor layer. The second semiconductor layer has a lower impurity concentration than an impurity concentration of the first semiconductor layer and a higher impurity concentration than an impurity concentration of the photoelectric conversion layer.

### DESCRIPTION

### Technical Field

The present disclosure relates to a photodetection device and an electronic device including the photodetection device.

### Background Art

As is well known, an imaging element included in an image sensor that detects visible light such as red light (R), green light (G), and blue light (B) usually includes a light receiving element (photodiode) formed on a silicon semiconductor substrate. Meanwhile, detection of infrared light has also been conventionally desired. However, since an energy band gap of silicon is 1.1 eV, it is impossible in principle to detect infrared light (IR) having a wavelength longer than 1.1 μm.

Therefore, there is an InGaAs image sensor capable of detecting infrared light by using InGaAs instead of silicon. It is known that this InGaAs image sensor is formed by forming a film of InGaAs on an InP substrate, and light is incident from the InP substrate side. However, in the InGaAs image sensor, visible light cannot be detected unless the InP substrate on the light incident side is removed.

Therefore, there is known a technique capable of increasing visible light sensitivity by thinning an n+InP layer on the light incident side (recombination preventing layer that suppresses dark current generation) in the InGaAs image sensor (for example, Patent Document 1).

### CITATION LIST

### Patent Document

Patent Document 1: Japanese Patent Application Laid-Open No. 2018-125538

### SUMMARY OF THE INVENTION

### Problems to be Solved by the Invention

Meanwhile, if the n+InP layer is thin, damage during a process reaches the InGaAs layer having a narrow band gap, and crystal defects are generated to cause white scratches. Furthermore, by lowering impurity concentration of the InP layer on the light incident side, photoelectric conversion becomes possible in the InP layer, and the visible light sensitivity is unlikely to be degraded even if the film is thickened, but white scratches are generated since a carrier generated by an interface defect is also read out.

The present disclosure has been made in view of such circumstances, and an object of the present disclosure is to provide a photodetection device and an electronic device capable of suppressing generation of crystal defects while maintaining visible light sensitivity.

### Solutions to Problems

One aspect of the present disclosure is a photodetection device including: a pixel region in which a plurality of pixels is arranged in a matrix, the plurality of pixels being capable of generating electric signals in accordance with infrared light and visible light incident from outside, in which the pixel region includes: a light transmitting layer including a first compound semiconductor and transmitting incident infrared light; and a photoelectric conversion layer configured to photoelectrically convert infrared light transmitted through the light transmitting layer, the photoelectric conversion layer being laminated on a surface of the light transmitting layer on a side opposite to a light incident surface and including a second compound semiconductor different from the first compound semiconductor, the light transmitting layer includes: a first semiconductor layer provided on the light incident surface side and having a thickness allowing transmission of the visible light; and a second semiconductor layer configured to photoelectrically convert visible light transmitted through the first semiconductor layer, the second semiconductor being laminated on a surface of the first semiconductor layer opposite to the light incident surface, and the second semiconductor layer has a lower impurity concentration than an impurity concentration of the first semiconductor layer and a higher impurity concentration than an impurity concentration of the photoelectric conversion layer.

Another aspect of the present disclosure relates to an electronic device including a photodetection device, the photodetection device including: a pixel region in which a plurality of pixels is arranged in a matrix, the plurality of pixels being capable of generating electric signals in accordance with infrared light and visible light incident from outside, in which the pixel region includes: a light transmitting layer including a first compound semiconductor and transmitting incident infrared light; and a photoelectric conversion layer configured to photoelectrically convert infrared light transmitted through the light transmitting layer, the photoelectric conversion layer being laminated on a surface of the light transmitting layer on a side opposite to a light incident surface and including a second compound semiconductor different from the first compound semiconductor, the light transmitting layer includes: a first semiconductor layer provided on the light incident surface side and having a thickness allowing transmission of the visible light; and a second semiconductor layer configured to photoelectrically convert visible light transmitted through the first semiconductor layer, the second semiconductor being laminated on a surface of the first semiconductor layer opposite to the light incident surface, and the second semiconductor layer has a lower impurity concentration than an impurity concentration of the first semiconductor layer and a higher impurity concentration than an impurity concentration of the photoelectric conversion layer.

### BRIEF DESCRIPTION OF DRAWINGS

FIG. 1 is a schematic plan layout view illustrating a configuration example of a photodetection device according to a first embodiment of the present disclosure.

FIG. 2 is a block diagram illustrating a configuration example of the photodetection device according to the first embodiment of the present disclosure.

FIG. 3 is a circuit diagram illustrating a configuration example of a readout circuit of the photodetection device according to the first embodiment of the present disclosure.

FIG. 4 is a main-part schematic cross-sectional view illustrating a configuration example of the photodetection device according to the first embodiment of the present disclosure.

FIG. 5 is a characteristic chart illustrating dependency on a film thickness and light transmittance of InP.

FIG. 6 is a cross-sectional view of a photodetection device illustrating an example of occurrence of process damage in a comparative example.

FIG. 7 is a cross-sectional view of a photodetection device illustrating another example of occurrence of process damage in a comparative example.

FIG. 8 is a view for describing a state where a carrier photoelectrically converted with visible light is transferred to a photoelectric conversion layer in the first embodiment of the present disclosure.

FIG. 9 is a view for describing a state where process damage becomes less likely to reach the photoelectric conversion layer in the first embodiment of the present disclosure.

FIG. 10 is a cross-sectional view of a photodetection device according to a second embodiment of the present disclosure.

FIG. 11 is a cross-sectional view of a photodetection device according to a third embodiment of the present disclosure.

FIG. 12 is a cross-sectional view of a photodetection device according to a fourth embodiment of the present disclosure.

FIG. 13 is a cross-sectional view of a photodetection device according to a fifth embodiment of the present disclosure.

FIG. 14A is a cross-sectional view of a photodetection device according to a sixth embodiment of the present disclosure.

FIG. 14B is a schematic plan view illustrating an arrangement pattern of pixels for infrared light and pixels for infrared light and visible light.

FIG. 15 is a block diagram illustrating a configuration example of an electronic device to which the present technology is applied.

FIG. 16 is a block diagram illustrating an example of schematic configuration of a vehicle control system.

FIG. 17 is an explanatory view illustrating an example of an installation position of a vehicle external information detection unit and an imaging section.

### MODE FOR CARRYING OUT THE INVENTION

Hereinafter, embodiments of the present disclosure will be described with reference to the drawings. In the description of the drawings referred to in the following description, the same or similar parts are denoted by the same or similar reference signs to avoid the description from being redundant. However, it should be noted that the drawings are schematic, and the relationship between thickness and planar dimension, the proportion of thickness of each device or each member, and the like differ from actual ones. Therefore, specific thicknesses and dimensions should be determined in consideration of the following description. Furthermore, it is needless to say that the drawings include portions having different dimensional relationships and ratios.

In this specification, a “first conductivity type” means one of a p-type or an n-type, and a “second conductivity type” means one of the p-type or the n-type different from the “first conductivity type”. Furthermore, “n” or “p” to which “+” or “−” is added means a semiconductor region having a relatively higher or lower impurity density than that of a semiconductor region to which “+” or “−” is not added. However, even in the semiconductor regions to which the same “n” and “n” are added, it does not mean that the impurity densities of the semiconductor regions are exactly the same.

In addition, the definitions of directions such as up and down or the like in the following description are merely definitions for convenience of description, and do not limit the technical idea of the present disclosure. For example, it goes without saying that if a target is observed while being rotated by 90°, the upward and downward directions are converted into rightward and leftward directions, and if the target is observed while being rotated by 180°, the upward and downward directions are inverted.

Note that the effects described in the present specification are merely examples and are not limited, and other effects may be provided.

### First Embodiment

### (Overall Configuration of Photodetection Device)

First, an overall configuration of a photodetection device 1A will be described.

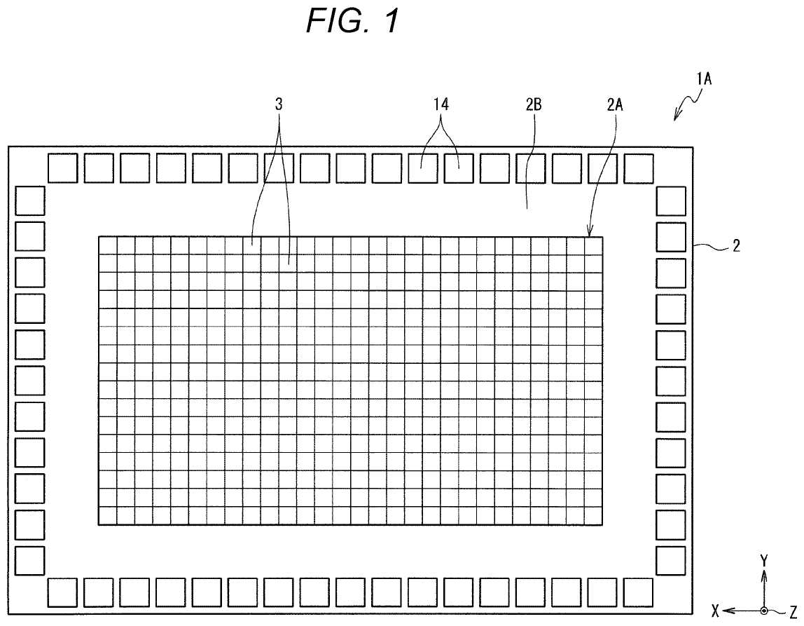

FIG. 1 is a schematic plan layout view illustrating a configuration example of a photodetection device according to a first embodiment of the present disclosure.

The photodetection device 1A according to the first embodiment of the present disclosure mainly includes a semiconductor chip 2 having a rectangular two-dimensional planar shape in plan view. That is, the photodetection device 1A is mounted on the semiconductor chip 2. The photodetection device 1A captures incident light from a subject via an optical lens (not illustrated), converts a light amount of the incident light formed on an imaging surface into an electrical signal in units of pixels, and outputs the electrical signal as a pixel signal.

The semiconductor chip 2 on which the photodetection device 1A is mounted includes a rectangular pixel region 2A provided in a central portion in a two-dimensional plane, and a peripheral region 2B arranged outside the pixel region 2A so as to surround the pixel region 2A.

The pixel region 2A is, for example, a light receiving surface that receives light condensed by the optical lens. Then, in the pixel region 2A, a plurality of pixels 3 is arranged in a matrix in the two-dimensional plane including an X direction and a Y direction. In other words, the pixels 3 are repeatedly arranged in each of the X direction and the Y direction orthogonal to each other in the two-dimensional plane.

A plurality of bonding pads (input-output terminals) 14 is arranged in the peripheral region 2B. The plurality of bonding pads 14 is arranged, for example, along four sides in the two-dimensional plane of the semiconductor chip 2. Each of the plurality of bonding pads 14 is an input-output terminal used when the semiconductor chip 2 is electrically connected to an external device.

### (Logic Circuit)

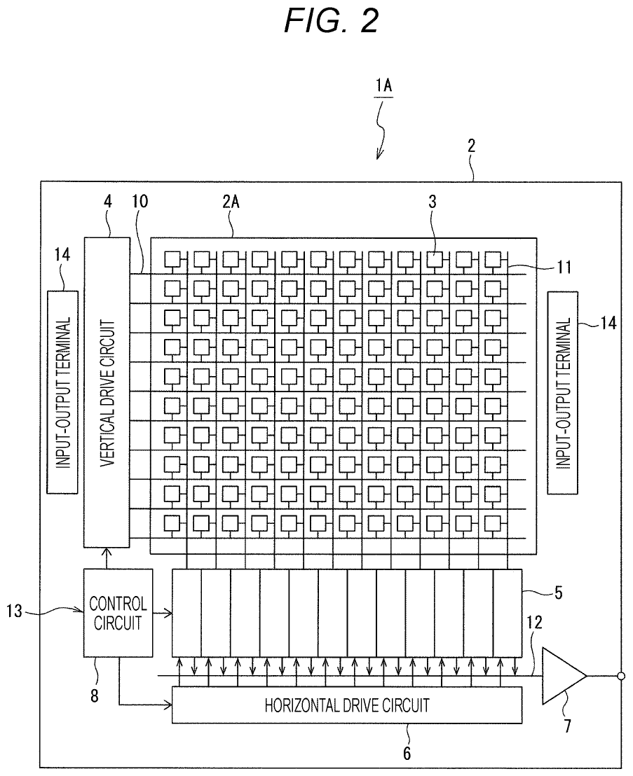

FIG. 2 is a block diagram illustrating a configuration example of the photodetection device 1A described above.

The semiconductor chip 2 includes a logic circuit 13 including a vertical drive circuit 4, a column signal processing circuit 5, a horizontal drive circuit 6, an output circuit 7, a control circuit 8, and the like. The logic circuit 13 includes, for example, a complementary MOS (CMOS) circuit including an n-channel conductive metal oxide semiconductor field effect transistor (MOSFET) and a p-channel conductive MOSFET.

The vertical drive circuit 4 includes, for example, a shift register. The vertical drive circuit 4 sequentially selects a desired pixel drive line 10, supplies a pulse for driving the pixel 3 to the selected pixel drive line 10, and drives each pixel 3 row by row. That is, the vertical drive circuit 4 selectively scans each pixel 3 in the pixel region 2A sequentially in a vertical direction in units of rows, and a pixel signal from the pixel 3 based on a signal charge generated according to the amount of received light by a photoelectric conversion element of each pixel 3 is supplied to the column signal processing circuit 5 through a vertical signal line 11.

The column signal processing circuit 5 is arranged, for example, on every column of the pixels 3 and performs signal processing, such as noise removal on signals output from the pixels 3 of one row, for every pixel column. For example, the column signal processing circuit 5 performs signal processing such as correlated double sampling (CDS) for removing pixel-specific fixed pattern noise and analog digital (AD) conversion.

The horizontal drive circuit 6 includes, for example, a shift register. The horizontal drive circuit 6 sequentially outputs horizontal scanning pulses to the column signal processing circuits 5 to sequentially select each of the column signal processing circuits 5, and causes each of the column signal processing circuits 5 to output the pixel signal subjected to the signal processing to a horizontal signal line 12.

The output circuit 7 performs signal processing on pixel signals sequentially supplied from each of the column signal processing circuits 5 through the horizontal signal line 12 and outputs processed signals. As the signal processing, for example, buffering, black level adjustment, column variation correction, various digital signal processing, and the like can be used.

The control circuit 8 generates a clock signal and a control signal, which are references for operations of the vertical drive circuit 4, the column signal processing circuit 5, the horizontal drive circuit 6, and the like on the basis of a vertical synchronization signal, a horizontal synchronization signal, and a master clock signal. Then, the control circuit 8 outputs the generated clock signal and control signal to the vertical drive circuit 4, the column signal processing circuit 5, the horizontal drive circuit 6, and the like.

### (Photoelectric Conversion Element and Readout Circuit)

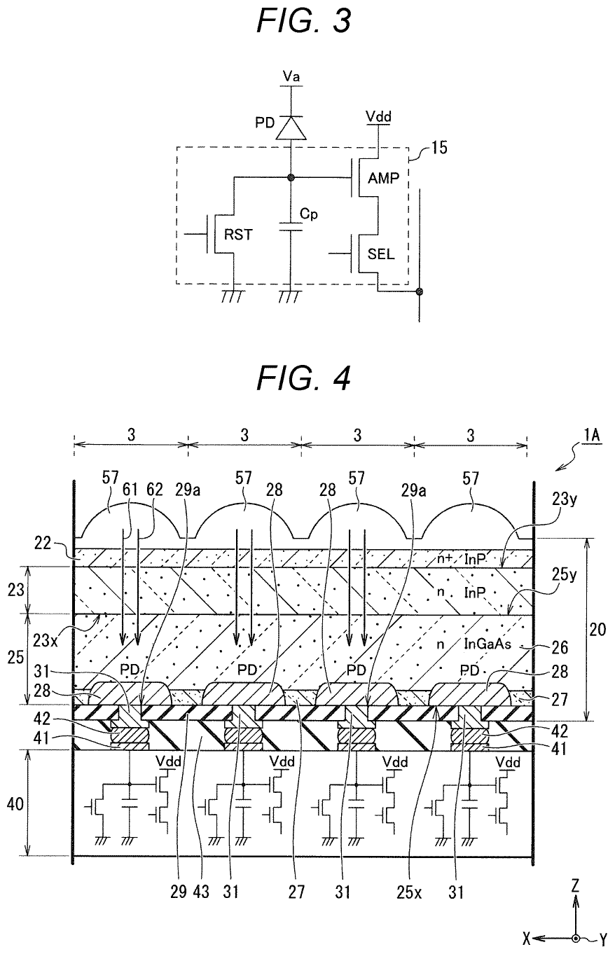

FIG. 3 is a circuit diagram illustrating a configuration example of a readout circuit 15 of the photodetection device 1A described above.

Each pixel 3 among the plurality of pixels includes a photoelectric conversion element PD. Then, the readout circuit 15 is connected to the photoelectric conversion element PD of each pixel 3. The photoelectric conversion element PD generates a charge (signal charge) corresponding to an amount of received light. A predetermined bias voltage Va is applied to a cathode side of the photoelectric conversion element PD.

The readout circuit 15 is connected to an anode side of the photoelectric conversion element PD. The readout circuit 15 includes a capacitive element Cp as a charge accumulation section (charge holding section), a reset transistor RST, an amplification transistor AMP, and a selection transistor SEL. These transistors (RST, AMP, SEL) each include, for example, a MOSFET having a silicon oxide film as a gate insulating film. Alternatively, these transistors (RST, AMP, SEL) may each include a metal insulator semiconductor FET (MISFET) having a silicon nitride (Si3N4) film or a laminated film of a silicon nitride film and a silicon oxide film as a gate insulating film.

The capacitive element Cp accumulates signal charges generated by the photoelectric conversion element PD. The capacitive element Cp is constituted by, for example, any one of a pn junction capacitance, a MOS capacitance, and a wiring capacitance.

When being turned on in response to the application of a reset signal to a gate electrode of the reset transistor RST, the reset transistor RST discharges the signal charges accumulated in the capacitive element Cp to reset a potential of the capacitive element Cp.

The amplification transistor AMP outputs a pixel signal corresponding to the storage potential of the capacitive element Cp. Specifically, the amplification transistor AMP constitutes a source follower circuit with a load MOS as a constant current source connected via the vertical signal line 11. The source follower circuit outputs a pixel signal indicating a level corresponding to the signal charges accumulated in the capacitive element Cp from the amplification transistor AMP to the column signal processing circuit 5 via the selection transistor SEL and the vertical signal line 11.

When turned on in response to the application of a selection signal to a gate electrode of the selection transistor SEL, the selection transistor SEL outputs the pixel signal of the pixel 3 to the column signal processing circuit 5 via the vertical signal line 11. A signal line through which the selection signal is transferred and a signal line through which the reset signal is transferred correspond to the pixel drive line 10 in FIG. 2.

### (Specific Configuration of Photodetection Device)

Next, a specific configuration of the photodetection device 1A will be described.

FIG. 4 is a main-part schematic cross-sectional view illustrating a configuration example of the photodetection device 1A.

The semiconductor chip 2 includes a photoelectric conversion substrate part 20 and a circuit substrate part 40 laminated to face each other. The photoelectric conversion substrate part 20 includes the pixel region 2A and the like described above. The circuit substrate part 40 includes the logic circuit 13, the bonding pad 14, the readout circuit 15, and the like described above.

(Photoelectric Conversion Substrate Part 20)

The photoelectric conversion substrate part 20 includes a first compound semiconductor layer 25 having a first surface 25x and a second surface 25y located on opposite sides of the first compound semiconductor layer 25, and a second compound semiconductor layer 23 on the second surface 25y side of the first compound semiconductor layer 25. The photoelectric conversion substrate part 20 includes a recombination preventing layer 22 as a second compound semiconductor layer disposed on a second surface 23y side of the second compound semiconductor layer 23. Each of the first compound semiconductor layer 25, the second compound semiconductor layer 23, and the recombination preventing layer 22 is provided in common for the individual pixels 3. Then, in the first compound semiconductor layer 25, the photoelectric conversion element PD described above is provided for each pixel 3. The recombination preventing layer 22 suppresses generation of dark current.

Here, the first surface 25x of the first compound semiconductor layer 25 may be referred to as an element formation surface or a main surface, and the second surface 25y may be referred to as a light incident surface or a back surface. Furthermore, a first surface 23x and the second surface 23y located on opposite sides of the second compound semiconductor layer 23 are also referred to as a main surface, and a light incident surface or a back surface, respectively.

Furthermore, as illustrated in FIG. 4, the photoelectric conversion substrate part 20 further includes a protective film 29 disposed on the first surface 25x side of the first compound semiconductor layer 25 to cover the first surface 25x. The protective film 29 is provided in common for the individual pixels 3. Furthermore, the photoelectric conversion substrate part 20 further includes a light shielding film (not illustrated), an antireflection film (not illustrated), a planarization film (not illustrated), and a microlens (on-chip lens) 57 on the light incident surface side of the recombination preventing layer 22. The recombination preventing layer 22 and the second compound semiconductor layer 23 constitute a light transmitting layer that transmits light having a wavelength in an infrared region (infrared light 61) and light having a wavelength in a visible region (visible light 62).

The first compound semiconductor layer 25 includes, for example, a photoelectric conversion layer 26 and a cap layer 27 in this order from the first surface 25x side. Then, the recombination preventing layer 22, the second compound semiconductor layer 23, the photoelectric conversion layer 26 of the first compound semiconductor layer 25, and the cap layer 27 of the first compound semiconductor layer 25 are epitaxial layers formed by being epitaxially grown on a growth substrate (not illustrated) in this order. That is, in the first compound semiconductor layer 25, the photoelectric conversion layer 26 and the cap layer 27 are covalently bonded to each other, and further, the photoelectric conversion layer 26 is covalently bonded to the second compound semiconductor layer 23.

The cap layer 27 is provided in common for all the pixels 3, for example, and is disposed between the protective film 29 and the photoelectric conversion layer 26. The cap layer 27 is provided with a plurality of contact regions 28 each including, for example, a semiconductor region (impurity diffusion region). The use of a compound semiconductor material that is wider in band gap (Eg) than the compound semiconductor material constituting the photoelectric conversion layer 26 for the cap layer 27 makes it possible to inhibit dark current. For the cap layer 27, for example, n-type indium phosphide (InP) can be used.

The plurality of contact regions 28 is arranged at intervals and is provided for each pixel 3 on a one-to-one basis. Then, a connection electrode (element-side connection electrode) 31 is individually connected to each contact region 28 through an opening 29a provided in the protective film 29.

The contact region 28 is for reading out signal charges generated in the photoelectric conversion layer 26 from each pixel 3, and contains, for example, p-type impurities. Examples of the p-type impurities include zinc (Zn) and the like. In this manner, a pn junction interface is formed between the contact region 28 and the cap layer 27 other than the contact region 28, and the pixels 3 adjacent to each other are electrically isolated. The contact region 28 is formed thicker than the cap layer 27, and is also provided in a part of the photoelectric conversion layer 26 in the thickness direction (Z direction).

The photoelectric conversion layer 26 between the cap layer 27 and the second compound semiconductor layer 23 is provided in common for all the pixels 3, for example. The photoelectric conversion layer 26 absorbs light having a predetermined wavelength, in the first embodiment, the infrared light 61 and the visible light 62, to generate signal charges, and the photoelectric conversion layer 26 includes, for example, a group III-V compound semiconductor material containing n-type impurities or an i-type group III-V compound semiconductor material. As the compound semiconductor material constituting the photoelectric conversion layer 26, for example, a compound semiconductor containing any of indium gallium arsenide (InGaAs) and indium gallium antimony (InGaAs/GaAsSb) can be adopted. In the first embodiment, i-type InGaAs is used as the photoelectric conversion layer 26. The photoelectric conversion layer 26 photoelectrically converts light having a wavelength in the infrared region and light having a wavelength in the visible region.

In the first embodiment, the recombination preventing layer 22 and the second compound semiconductor layer 23 are provided in common for all the pixels 3. The recombination preventing layer 22 and the second compound semiconductor layer 23 also function as an electrode common for the individual pixels 3, and discharge (cathode) charges not used as signal charges among charges generated in the photoelectric conversion layer 26. For example, in a case where holes are read out from the connection electrode 31 as signal charges, for example, electrons can be discharged through the recombination preventing layer 22 and the second compound semiconductor layer 23. A predetermined bias voltage Va is applied to the recombination preventing layer 22 and the second compound semiconductor layer 23.

The connection electrode (element-side connection electrode) 31 is an electrode (anode) to which a voltage for reading out signal charges (holes or electrons, hereinafter, for convenience, the description will be made on the assumption that the signal charges are holes) generated in the photoelectric conversion layer 26 is supplied, and is provided in the pixel region 2A for each pixel 3. That is, the photoelectric conversion element PD including the connection electrode 31, the photoelectric conversion layer 26, and the recombination preventing layer 22 and the second compound semiconductor layer 23 that also function as electrodes is provided for each pixel 3. Then, the connection electrode 31 functions as an anode-side electrode of the photoelectric conversion element PD, and the recombination preventing layer 22 and the second compound semiconductor layer 23 function as a cathode-side electrode of the photoelectric conversion element PD.

The connection electrode 31 includes, for example, any one of titanium (Ti), tungsten (W), titanium nitride (TiN), platinum (Pt), gold (Au), germanium (Ge), palladium (Pd), zinc (Zn), nickel (Ni), or aluminum (Al), or an alloy containing at least one of them. The connection electrode 31 may be a single film of such a constituent material, or may be a laminated film obtained by combining two or more of the constituent materials. For example, the connection electrode 31 includes a laminated film of titanium and tungsten, and has a film thickness of about several tens nm to several hundreds nm.

As illustrated in FIG. 4, the protective film 29 is provided between the first compound semiconductor layer 25 and an insulating layer 43. The protective film 29 includes, for example, an oxide such as silicon oxide (SiOx) or aluminum oxide (A1₂O₃). The protective film 29 may have a laminated structure in which a plurality of films is laminated. The protective film 29 may include, for example, a silicon (Si) insulating material such as silicon oxynitride (SiON), carbon-containing silicon oxide (SiOC), silicon nitride (SiN), and silicon carbide (SiC). The thickness of the protective film 29 is, for example, about several tens nm to several hundreds nm.

As illustrated in FIG. 4, the recombination preventing layer 22 and the second compound semiconductor layer 23 are formed by an n-type compound semiconductor having an impurity concentration higher than that of the photoelectric conversion layer 26 of the first compound semiconductor layer 25, and also have a function as an electrode as described above.

As a material of the recombination preventing layer 22 and the second compound semiconductor layer 23, a compound semiconductor containing any of InP, InGaAsP, InGaAlAs, InAlAs, InAlAsSb, and AlAsSb can be adopted. In the first embodiment, InP containing n-type impurities is used as the compound semiconductor material constituting the recombination preventing layer 22 and the second compound semiconductor layer 23. The second compound semiconductor layer 23 and the first compound semiconductor layer 25 described above include different compound semiconductor materials.

### (Film Thickness and Light Transmittance of InP)

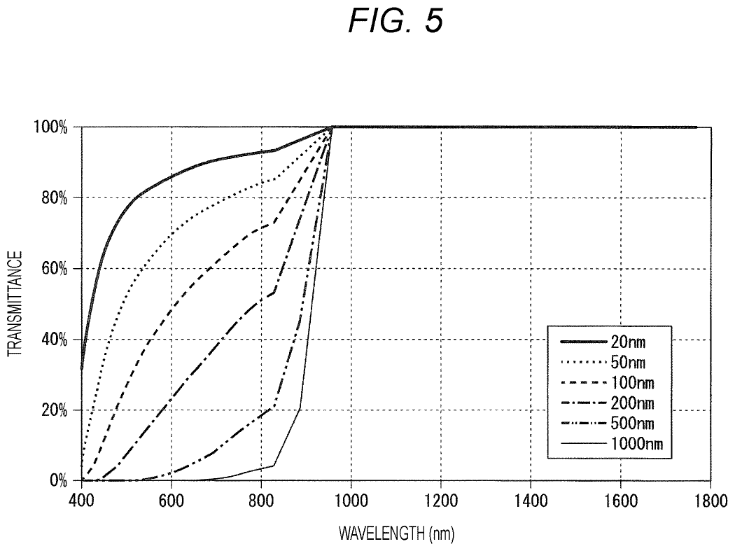

FIG. 5 is a characteristic chart illustrating dependency on a film thickness and light transmittance of InP. FIG. 5 illustrates cases where the film thickness of InP is 20 nm, 50 nm, 100 nm, 200 nm, 500 nm, and 1000 nm. The wavelength range of infrared light is approximately from 780 nm to 1 mm. The wavelength range of visible light is approximately from a lower limit of 360 nm to 400 nm to an upper limit of 760 nm to 830 nm.

As shown in FIG. 5, when the wavelength band of light is approximately less than or equal to 950 nm, the light transmittance depends on the film thickness, the light transmittance increases as the film thickness decreases, and the transmittance decreases as the film thickness increases.

As illustrated in FIG. 4, the microlens 57 is provided on the light incident surface side of the recombination preventing layer 22. The microlens 57 is provided for each pixel 3 in the pixel region 2A, and is arranged in a matrix corresponding to the arrangement of the plurality of pixels 3. The microlens 57 condenses irradiation light and allows the condensed light to efficiently enter the pixel 3. The microlens 57 includes, for example, a resin material.

### (Circuit Substrate Part 40)

Although no specific configuration is illustrated in FIG. 4, the circuit substrate part 40 includes a semiconductor substrate including, for example, single crystal silicon, and a multilayer wiring layer disposed on a first surface side of the semiconductor substrate opposite from a second surface of the semiconductor substrate in the thickness direction (Z direction). The semiconductor substrate of the circuit substrate part 40 is provided with an active element and a passive element included in circuits such as the logic circuit 13 and the readout circuit 15 described above. In FIG. 4, the readout circuit 15 illustrated in FIG. 3 is illustrated without the reference signs.

As illustrated in FIG. 4, a connection electrode 41 is provided in an uppermost wiring layer of the circuit substrate part 40. The connection electrode 41 is disposed corresponding to the connection electrode 31 of the photoelectric conversion substrate part 20. Then, the connection electrode 41 is electrically connected to the readout circuit 15.

The connection electrode 41 of the circuit substrate part 40 is electrically and mechanically connected to the connection electrode 31 of the photoelectric conversion substrate part 20 via a bump electrode 42. Then, the insulating layer 43 is provided in a space between the circuit substrate part 40 and the photoelectric conversion substrate part 20 except for the bump electrode 42. The circuit substrate part 40 and the photoelectric conversion substrate part 20 are joined together by the bump electrode 42 and the insulating layer 43. The photoelectric conversion element PD of the circuit substrate part 40 has the anode side electrically connected to the readout circuit 15 via the connection electrode 31, the bump electrode 42, and the connection electrode 41.

### <Comparative Example of Embodiment>

Meanwhile, in the InGaAs image sensor, the visible light sensitivity can be increased by reducing a film thickness of the recombination preventing layer 22, but damage during the process reaches the photoelectric conversion layer 26 having a narrower band gap than the recombination preventing layer 22.

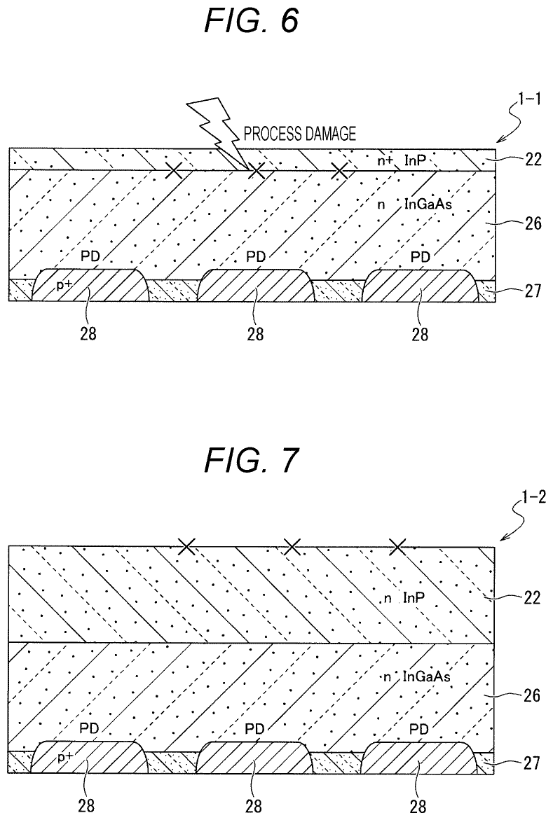

FIG. 6 is a cross-sectional view of a photodetection device 1-1 illustrating an example of occurrence of process damage in a comparative example. In FIG. 6, the same components as those in FIG. 4 described above are denoted by the same reference signs, and detailed description thereof is omitted.

In FIG. 6, in the photodetection device 1-1, if a film thickness of the recombination preventing layer 22 is thin, damage during the process reaches the photoelectric conversion layer 26, and crystal defects are generated to cause white scratches. These white scratches cause a white portion to remain in an image when the image is created.

Meanwhile, a method of lowering the impurity concentration of the recombination preventing layer 22 is also conceivable.

FIG. 7 is a cross-sectional view of a photodetection device 1-2 illustrating another example of occurrence of process damage in a comparative example. In FIG. 7, the same components as those in FIG. 4 described above are denoted by the same reference signs, and detailed description thereof is omitted.

In FIG. 7, in the photodetection device 1-2, by lowering the impurity concentration of the recombination preventing layer 22, the photoelectric conversion becomes possible in the recombination preventing layer 22, and the visible light sensitivity is unlikely to be degraded even if the film thickness of the recombination preventing layer 22 is increased. However, white scratches are generated since a carrier generated by an interface defect is also read out.

### <Solving Means of First Embodiment>

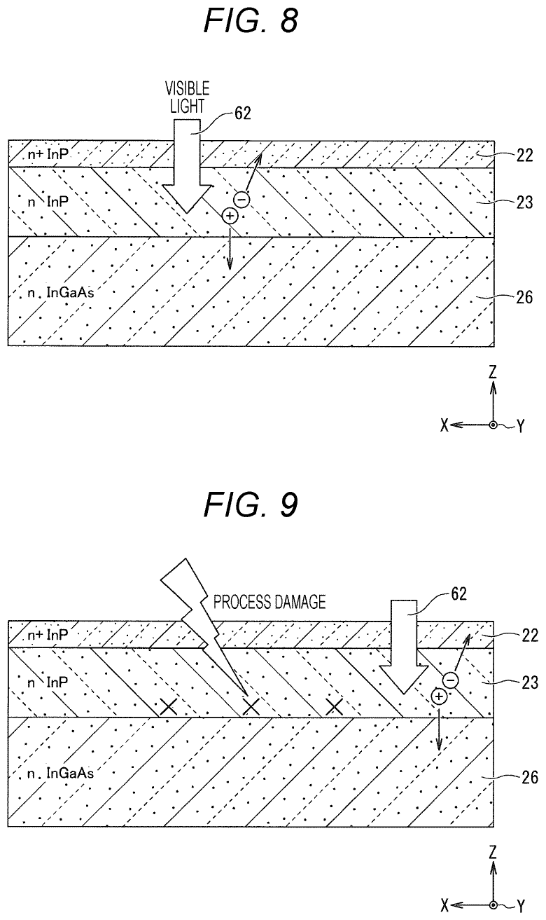

For the problems described above, in the first embodiment of the present disclosure, as illustrated in FIGS. 8 and 9, the second compound semiconductor layer 23 having an impurity concentration lower than the impurity concentration of the recombination preventing layer 22 is provided between the recombination preventing layer 22 and the photoelectric conversion layer 26.

A total film thickness of the recombination preventing layer 22 and the second compound semiconductor layer 23 illustrated in FIG. 8 is the same as the film thickness of the recombination preventing layer 22 of the previous InGaAs image sensor. By doing in this way, since the visible light 62 is photoelectrically converted by the second compound semiconductor layer 23, the visible light sensitivity is increased. Furthermore, even if the total InP layer is thickened, if the recombination preventing layer 22 is thinned, process damage is less likely to reach the photoelectric conversion layer 26 as illustrated in FIG. 9 while the visible light sensitivity is maintained, and generation of crystal defects in InGaAs, which are a source of white scratches, is suppressed.

Note that a film thickness of the recombination preventing layer 22 is 5×10¹⁷ cm⁻³ or more and 30 nm or less. Furthermore, a film thickness of the second compound semiconductor layer 23 is 1×10¹⁷ cm⁻³ or more and 1×10¹⁸ cm⁻³ or less. A film thickness of the photoelectric conversion layer 26 is 1×10¹⁷ cm⁻³ or less.

Moreover, the impurity concentration of the second compound semiconductor layer 23 is lower than that of the recombination preventing layer 22 and higher than that of the photoelectric conversion layer 26. As the impurities of the recombination preventing layer 22 and the second compound semiconductor layer 23, either Si (silicon) or S (sulfur) is used in the case of n-type.

### <Effects Produced by First Embodiment>

As described above, according to the first embodiment, by providing the second compound semiconductor layer 23 having a lower impurity concentration than that of the recombination preventing layer 22 and a higher impurity concentration than that of an impurity concentration of the photoelectric conversion layer 26 between the recombination preventing layer 22 and the photoelectric conversion layer 26 on the light incident side, a carrier of the visible light 62 photoelectrically converted by the second compound semiconductor layer 23 can be transferred to the photoelectric conversion layer 26, which makes it possible to reduce process damage given to the photoelectric conversion layer 26, which is a source of white scratches, while maintaining visible light sensitivity.

### Second Embodiment

In a second embodiment of the present disclosure, an example will be described in which a photoelectric conversion layer, a recombination preventing layer, and a second compound semiconductor layer are p-type.

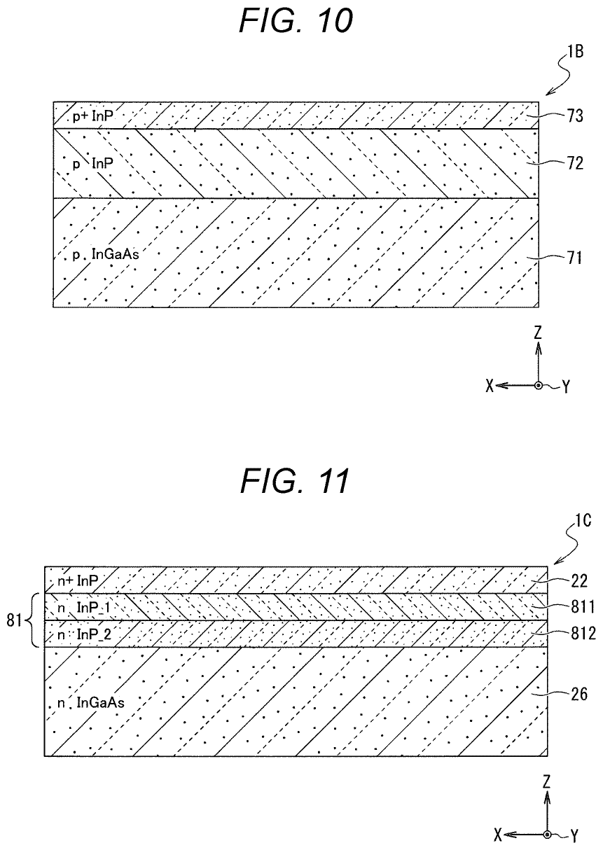

FIG. 10 is a cross-sectional view of a photodetection device 1B according to the second embodiment of the present disclosure. In the photodetection device 1B, a photoelectric conversion layer 71, a second compound semiconductor layer 72, and a recombination preventing layer 73 are laminated in this order along a thickness direction (a direction indicated by an arrow Z in FIG. 10).

A film thickness of the recombination preventing layer 73 is 5×10¹⁷ cm⁻³ or more and 30 nm or less. Furthermore, a film thickness of the second compound semiconductor layer 72 is 1 x 1017 cm⁻³ or more and 1×10¹⁸ cm⁻³ or less. A film thickness of the photoelectric conversion layer 71 is 1×10¹⁷ cm⁻³ or less.

Moreover, the impurity concentration of the second compound semiconductor layer 72 is lower than that of the recombination preventing layer 73 and higher than that of the photoelectric conversion layer 71. As impurities of the recombination preventing layer 73 and the second compound semiconductor layer 72, any of Mg (magnesium), Cd (cadmium), Al (aluminum), and Zn (zinc) is used.

### <Effects Produced by Second Embodiment>

As described above, according to the second embodiment, similar effects to those of the first embodiment described above can be obtained.

### Third Embodiment

In a third embodiment of the present disclosure, an example will be described in which a second compound semiconductor layer is formed by laminating layers of a plurality of stages.

FIG. 11 is a cross-sectional view of a photodetection device 1C according to the third embodiment of the present disclosure. In FIG. 11, the same components as those in FIG. 8 described above are denoted by the same reference signs, and detailed description thereof is omitted.

A second compound semiconductor layer 81 includes a first-stage layer (n InP_1) 811 and a second-stage layer (n InP_2) 812 laminated on a photoelectric conversion layer 26 side of the first-stage layer 811. An impurity concentration of the second compound semiconductor layer 81 is lower than that of a recombination preventing layer 22 and higher than that of the photoelectric conversion layer 26, and an impurity concentration of the first-stage layer 811 is higher than that of the second-stage layer 812.

### <Effects Produced by Third Embodiment>

As described above, according to the third embodiment, the second compound semiconductor layer 81 includes the first-stage layer 811 and the second-stage layer 812, and the impurity concentration of the second-stage layer 812 located on the photoelectric conversion layer 26 side is made lower than the impurity concentration of the first-stage layer 811. Therefore, it is possible to reduce a manufacturing cost of the photodetection device 1C, and transfer the photoelectrically converted carrier of visible light 62 to the photoelectric conversion layer 26.

Note that, in the third embodiment, the second compound semiconductor layer 81 may include layers of two or more stages as a plurality of stages. By doing in this way, by reducing the impurity concentration in every stage toward the photoelectric conversion layer 26, a photoelectrically converted carrier of the visible light 62 can be further transferred to the photoelectric conversion layer 26.

### Fourth Embodiment

In a fourth embodiment of the present disclosure, an example will be described in which a second compound semiconductor layer is formed in gradation.

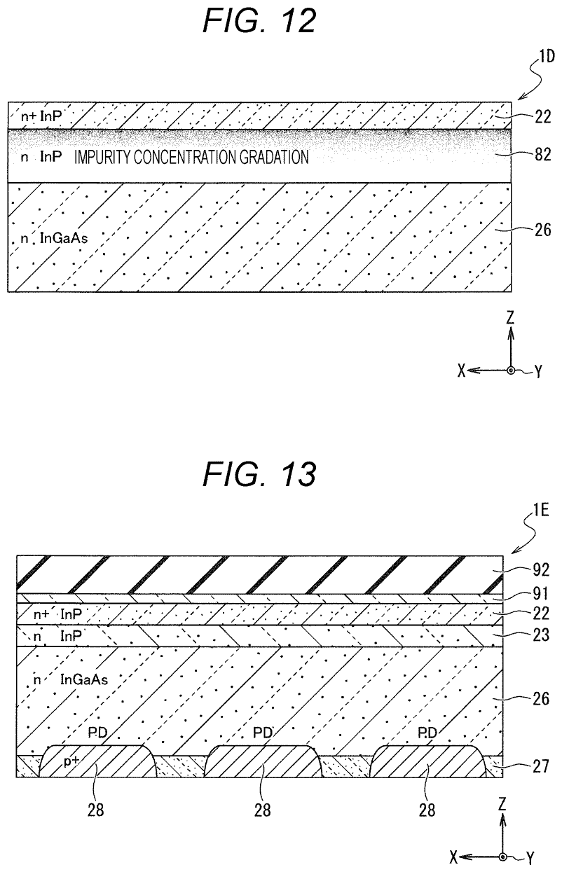

FIG. 12 is a cross-sectional view of a photodetection device 1D according to the fourth embodiment of the present disclosure. In FIG. 12, the same components as those in FIG. 8 described above are denoted by the same reference signs, and detailed description thereof is omitted.

A second compound semiconductor layer 82 has an impurity concentration lower than that of a recombination preventing layer 22 and higher than that of a photoelectric conversion layer 26, and the impurity concentration is lower toward the photoelectric conversion layer 26 side in gradation.

### <Effects Produced by Fourth Embodiment>

As described above, according to the fourth embodiment, by lowering the impurity concentration of the second compound semiconductor layer 82 in gradation toward the photoelectric conversion layer 26, a photoelectrically converted carrier of visible light 62 easily drops into the photoelectric conversion layer 26.

### Fifth Embodiment

In a fifth embodiment of the present disclosure, an example will be described in which a transparent electrode and a passivation layer are disposed on a light incident side of a recombination preventing layer.

FIG. 13 is a cross-sectional view of a photodetection device 1E according to the fifth embodiment of the present disclosure. In FIG. 13, the same components as those in FIG. 4 described above are denoted by the same reference signs, and detailed description thereof is omitted.

A transparent electrode 91 is disposed on a light incident side of a recombination preventing layer 22. Then, a passivation layer 92 is disposed on a light incident side of the transparent electrode 91. The transparent electrode 91 is in contact with and electrically connected to the recombination preventing layer 22. A predetermined bias voltage Va is applied to the transparent electrode 91. As the transparent electrode 91, a material such as, for example, indium tin oxide (ITO) that can transmit infrared light 61 and visible light 62 can be used.

As the passivation layer 92, a material capable of transmitting the infrared light 61 and the visible light 62, such as, for example, silicon oxide (SiO₂), silicon nitride (SiN), or aluminum oxide (Al₂O₃), can be used. Furthermore, the passivation layer 92 also functions as an electrode, and a predetermined bias voltage Va may be applied thereto.

### <Effects Produced by Fifth Embodiment>

As described above, according to the fifth embodiment, the predetermined bias voltage Va can be more stably applied to a cathode side of a photoelectric conversion element PD included in each pixel 3.

Note that, in the fifth embodiment, an example in which both the transparent electrode 91 and the passivation layer 92 are provided has been described, but only either the transparent electrode 91 or the passivation layer 92 may be provided.

### Sixth Embodiment

In a sixth embodiment of the present disclosure, an example will be described in which a film thickness of a recombination preventing layer is different for every pixel.

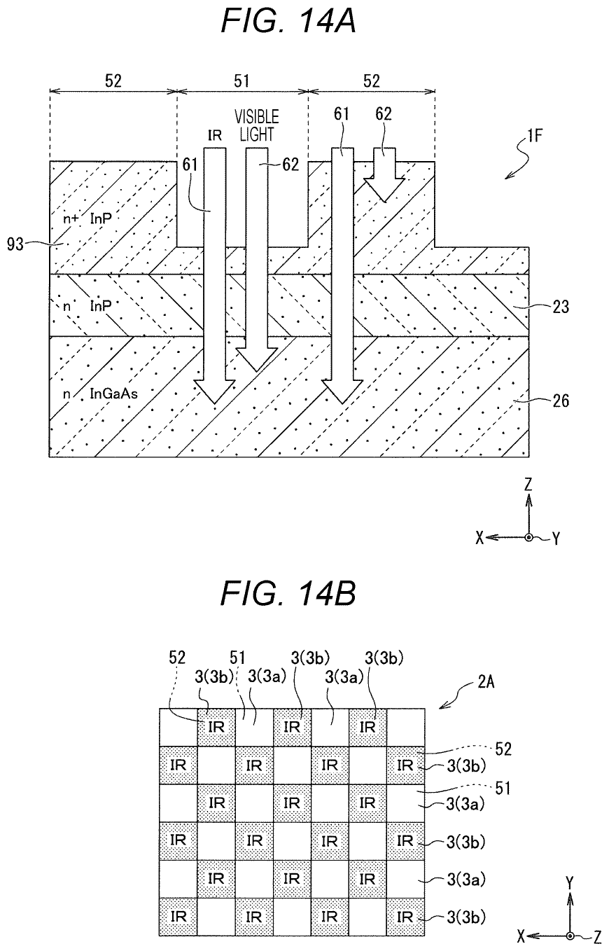

FIG. 14A is a cross-sectional view of a photodetection device 1E according to the sixth embodiment of the present disclosure. In FIG. 13, the same components as those in FIG. 4 described above are denoted by the same reference signs, and detailed description thereof is omitted. FIG. 14B is a schematic plan view illustrating an arrangement pattern of pixels 3b for infrared light 61 and pixels 3a for the infrared light 61 and visible light 62.

The photodetection device 1F includes a recombination preventing layer 93 that forms: a first light transmitting part 51 that is provided on a light incident side of a second compound semiconductor layer 23 and is capable of transmitting the infrared light 61 and the visible light 62; and a second light transmitting part 52 that transmits the infrared light 61 and blocks transmission of the visible light 62. A film thickness of the recombination preventing layer 93 in the second light transmitting part 52 is desirably 1 μm or more.

As illustrated in FIG. 14B, the pixel 3a including the first light transmitting part 51 and the pixel 3b including the second light transmitting part 52 are alternately and repeatedly arranged in each of the X direction and the Y direction orthogonal to each other in plan view.

In the pixel 3a, a pixel signal obtained by photoelectrically converting the infrared light 61 is obtained. Then, a pixel signal of the visible light 62 is obtained by removing (subtracting) the pixel signal (infrared light 61) of the pixel 3b from the pixel signal (infrared light 61+visible light 62) of the pixel 3a. Therefore, according to the photodetection device 1F according to the sixth embodiment, pixel signals for two wavelengths of the infrared light 61 and the visible light 62 can be simultaneously obtained by one device.

### <Effects Produced by Sixth Embodiment>

As described above, according to the sixth embodiment, by changing the film thickness of the recombination preventing layer 93 for every pixel 3, it is possible to easily form the first light transmitting part 51 that transmits the infrared light 61 and the visible light 62 and the second light transmitting part 52 that transmits the infrared light 61 and blocks transmission of the visible light 62. Therefore, according to the photodetection device IF according to the sixth embodiment, it is possible to simultaneously obtain pixel signals for two wavelengths of the infrared light 61 and the visible light 62 at low cost.

### Other Embodiments

The present technology has been described as above according to the first to sixth embodiments, but it should not be understood that the description and drawings forming a part of this disclosure limit the present technology. It will be apparent to those skilled in the art that various alternative embodiments, examples, and operation techniques can be included in the present technology when understanding the spirit of the technical content disclosed in the first to sixth embodiments described above. Furthermore, the configurations disclosed in the first to sixth embodiments can be appropriately combined within a range in which no contradiction occurs. For example, configurations disclosed in a plurality of different embodiments may be combined, or configurations disclosed in a plurality of different modifications of the same embodiment may be combined.

### <Example of Applications to Electronic Devices>

The photodetection device described above can be applied to various electronic devices such as, for example, an imaging device such as a digital still camera and a digital video camera, a mobile phone with an imaging function, or other devices having an imaging function.

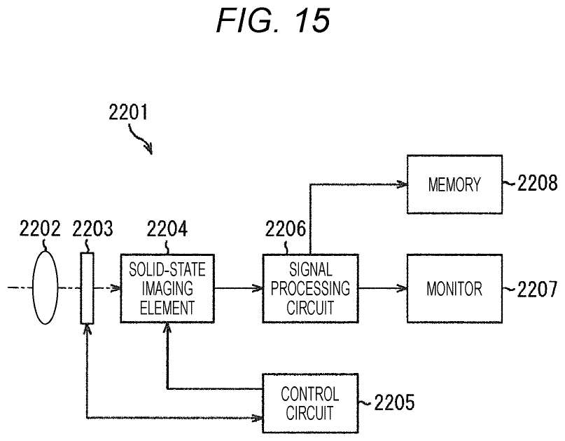

FIG. 15 is a block diagram illustrating a configuration example of an imaging device as an electronic device to which the present technology is applied.

An imaging device 2201 illustrated in FIG. 15 includes an optical system 2202, a shutter device 2203, a solid-state imaging element 2204 as a photodetection device, a control circuit 2205, a signal processing circuit 2206, a monitor 2207, and two memories 2208, and can capture a still image and a moving image.

The optical system 2202 includes one or a plurality of lenses, and guides light from a subject (incident light) to the solid-state imaging element 2204 to form an image on a light receiving surface of the solid-state imaging element 2204.

The shutter device 2203 is disposed between the optical system 2202 and the solid-state imaging element 2204, and controls a light irradiation period and a light shielding period for the solid-state imaging element 2204 under the control of the control circuit 2205.

The solid-state imaging element 2204 includes a package including the above-described solid-state imaging element. The solid-state imaging element 2204 accumulates signal charges for a certain period according to the light formed as an image on the light-receiving surface via the optical system 2202 and the shutter device 2203. The signal charges stored in the solid-state imaging element 2204 are transferred according to a drive signal (timing signal) supplied from the control circuit 2205.

The control circuit 2205 outputs the drive signal to control a transfer operation of the solid-state imaging element 2204 and a shutter operation of the shutter device 2203, to drive the solid-state imaging element 2204 and the shutter device 2203.

The signal processing circuit 2206 performs various types of signal processing on the signal charges output from the solid-state imaging element 2204. An image (image data) obtained by the signal processing applied by the signal processing circuit 2206 is supplied to the monitor 2207 to be displayed or supplied to the memory 2208 to be stored (recorded).

Also in the imaging device 2201 configured as described above, the photodetection devices 1A, 1B, 1C, 1D, 1E, and IF can be applied instead of the solid-state imaging element 2204 described above.

### <Example of Application to Mobile Body>

The technology according to the present disclosure (the present technology) can be applied to various products. For example, the technology according to the present disclosure may be realized as a device equipped on any type of mobile bodies, such as an automobile, an electric car, a hybrid electric car, a motorcycle, a bicycle, personal mobility, an airplane, a drone, a ship, a robot, and the like.

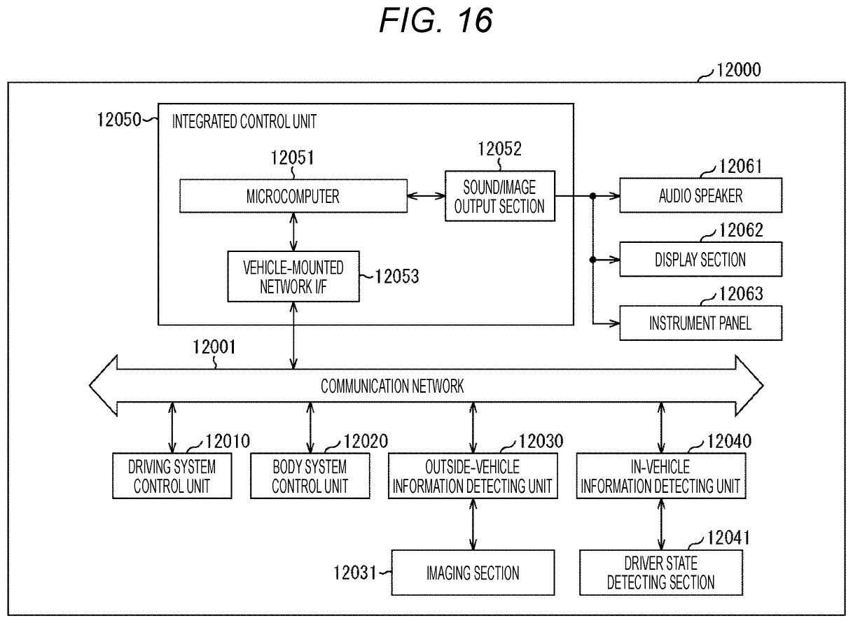

FIG. 16 is a block diagram illustrating a schematic configuration example of a vehicle control system as an example of a mobile body control system to which the technology according to the present disclosure can be applied.

The vehicle control system 12000 includes a plurality of electronic control units connected to each other via a communication network 12001. In the example illustrated in FIG. 16, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of information about the outside of the vehicle acquired by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 22, an audio speaker 12061, a display section 12062, and an instrument panel 12063 are illustrated as output devices. The display section 12062 may, for example, include at least one of an on-board display and a head-up display.

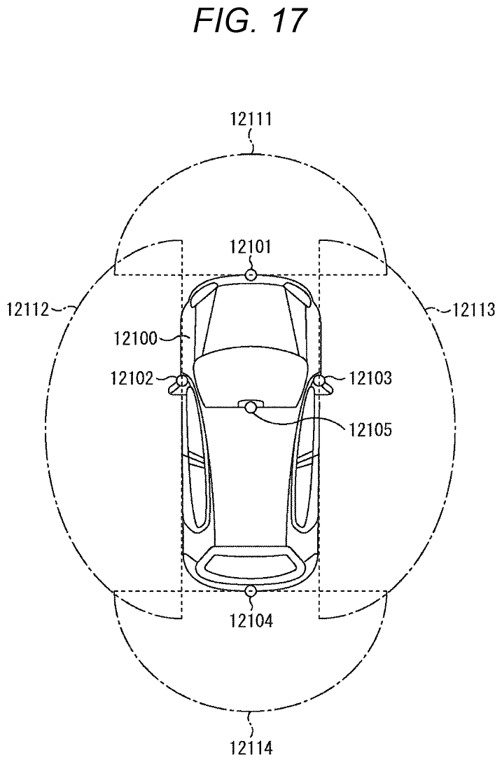

FIG. 17 is a diagram illustrating an example of an installation position of the imaging section 12031.

In FIG. 17, a vehicle 12100 has imaging sections 12101, 12102, 12103, 12104, and 12105 as the imaging section 12031.

The imaging sections 12101, 12102, 12103, 12104, 12105 are provided, for example, at positions such as a front nose, a sideview mirror, a rear bumper, a back door, and an upper portion of a windshield in the interior of the vehicle 12100. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The forward images obtained by the imaging sections 12101 and 12105 are used mainly to detect a preceding vehicle, a pedestrian, an obstacle, a traffic signal, a traffic sign, a lane, or the like.

Note that, FIG. 17 illustrates an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to the imaging section 12031 and the like, for example, among the components described above. Specifically, the present invention can be applied to the photodetection device 1A of FIG. 1, the photodetection device 1B of FIG. 10, the photodetection device 1C of FIG. 11, the photodetection device 1D of FIG. 12, the photodetection device 1E of FIG. 13, and the photodetection device 1F of FIG. 14A.

Note that the present disclosure can also have the following configurations.

(1)

A photodetection device including:
a pixel region in which a plurality of pixels is arranged in a matrix, the plurality of pixels being capable of generating electric signals in accordance with infrared light and visible light incident from outside, in which
the pixel region includes:
a light transmitting layer including a first compound semiconductor and transmitting incident infrared light; and
a photoelectric conversion layer configured to photoelectrically convert infrared light transmitted through the light transmitting layer, the photoelectric conversion layer being laminated on a surface of the light transmitting layer on a side opposite to a light incident surface and including a second compound semiconductor different from the first compound semiconductor,
the light transmitting layer includes:
a first semiconductor layer provided on the light incident surface side and having a thickness allowing transmission of the visible light; and
a second semiconductor layer configured to photoelectrically convert visible light transmitted through the first semiconductor layer, the second semiconductor being laminated on a surface of the first semiconductor layer opposite to the light incident surface, and
the second semiconductor layer has a lower impurity concentration than an impurity concentration of the first semiconductor layer and a higher impurity concentration than an impurity concentration of the photoelectric conversion layer.
   (2)

The photodetection device according to (1) above, further including:
a transparent electrode disposed on the light incident surface side of the light transmitting layer and transmitting the infrared light and the visible light.
   (3)

The photodetection device according to (1) above, further including:
a passivation layer disposed on the light incident surface side of the light transmitting layer and transmitting the infrared light and the visible light.
   (4)

The photodetection device according to (1) above, further including:
a transparent electrode and a passivation layer that are disposed on the light incident surface side of the light transmitting layer and transmit the infrared light and the visible light.
   (5)

The photodetection device according to (1) above, in which
the second semiconductor layer is formed by laminating layers of a plurality of stages, and
an impurity concentration of a first stage located on the photoelectric conversion layer side among the plurality of stages is lower than an impurity concentration of a second stage laminated on the light incident surface side of the first stage.
   (6)

The photodetection device according to (1) above, in which
the second semiconductor layer has an impurity concentration becoming lower in gradation toward the photoelectric conversion layer side.
   (7)

The photodetection device according to (1) above, in which
the first semiconductor layer has a different thickness for each of the pixels.
   (8)

The photodetection device according to (7) above, in which
the first semiconductor layer has a thickness allowing transmission of the visible light in a first pixel among a plurality of pixels, and has a thickness that prevents transmission of the visible light in a second pixel.
   (9)

The photodetection device according to (1) above, in which
the light transmitting layer includes any of InP, InGaAsP, InGaAlAs, InAlAs, InAlAsSb, and AlAsSb.
   (10)

The photodetection device according to (1) above, in which
the photoelectric conversion layer contains any of InGaAs and InGaAs/GaAsSb.
   (11)

The photodetection device according to (1) above, in which
the light transmitting layer and the photoelectric conversion layer are n-type, and contain any of Si and S as an impurity.
   (12)

The photodetection device according to (1) above, in which
the light transmitting layer and the photoelectric conversion layer are p-type, and contain any of Mg, Cd, Al, and Zn as an impurity.
   (13)

The photodetection device according to (1) above, in which
the first semiconductor layer has a thickness of 5×10¹⁷ cm⁻³ or more and 30 nm or less.
   (14)

An electronic device including
a photodetection device, the photodetection device including:
a pixel region in which a plurality of pixels is arranged in a matrix, the plurality of pixels being capable of generating electric signals in accordance with infrared light and visible light incident from outside, in which
the pixel region includes:
a light transmitting layer including a first compound semiconductor and transmitting incident infrared light; and
a photoelectric conversion layer configured to photoelectrically convert infrared light transmitted through the light transmitting layer, the photoelectric conversion layer being laminated on a surface of the light transmitting layer on a side opposite to a light incident surface and including a second compound semiconductor different from the first compound semiconductor,
the light transmitting layer includes:
a first semiconductor layer provided on the light incident surface side and having a thickness allowing transmission of the visible light; and
a second semiconductor layer configured to photoelectrically convert visible light transmitted through the first semiconductor layer, the second semiconductor being laminated on a surface of the first semiconductor layer opposite to the light incident surface, and
the second semiconductor layer has a lower impurity concentration than an impurity concentration of the first semiconductor layer and a higher impurity concentration than an impurity concentration of the photoelectric conversion layer.

### REFERENCE SIGNS LIST

1A, 1B, 1C, 1D, 1E, 1F Photodetection device
2 Semiconductor chip
2A Pixel region
2B Peripheral region
3, 3a, 3b Pixel
4 Vertical drive circuit
5 Column signal processing circuit
6 Horizontal drive circuit
7 Output circuit
8 Control circuit
10 Pixel drive line
11 Vertical signal line
12 Horizontal signal line
13 Logic circuit
14 Bonding pad (input-output terminal)
15 Readout circuit
20 Photoelectric conversion substrate part
22, 73, 93 Recombination preventing layer
23, 72, 81, 82 Second compound semiconductor layer
23x, 25x First surface
23y, 25y Second surface
25 First compound semiconductor layer
26, 71 Photoelectric conversion layer
27 Cap layer
28 Contact region
29 Protective film
29a Opening
31, 41 Connection electrode
40 Circuit substrate part
42 Bump electrode
43 Insulating layer
51 First light transmitting part
52 Second light transmitting part
57 Microlens (on-chip lens)
61 Infrared light
62 Visible light
91 Transparent electrode
92 Passivation layer
811 First stage layer
812 Second stage layer
2201 Imaging device
2202 Optical system
2203 Shutter device
2204 Solid-state imaging element
2205 Control circuit
2206 Signal processing circuit
2207 Monitor
2208 Memory
12000 Vehicle control system
12001 Communication network
12010 Driving system control unit
12020 Body system control unit
12030 Outside-vehicle information detecting unit
12031 Imaging section
12040 In-vehicle information detecting unit
12041 Driver state detecting section
12050 Integrated control unit
12051 Microcomputer
12052 Sound/image output section
12061 Audio speaker
12062 Display section
12063 Instrument panel
12100 Vehicle
12101, 12102, 12103, 12104, 12105 Imaging section
12111, 12112, 12113, 12114 Imaging range

1. A photodetection device comprising:
a pixel region in which a plurality of pixels is arranged in a matrix, the plurality of pixels being capable of generating electric signals in accordance with infrared light and visible light incident from outside, wherein
the pixel region includes:
a light transmitting layer including a first compound semiconductor and transmitting incident infrared light; and
a photoelectric conversion layer configured to photoelectrically convert infrared light transmitted through the light transmitting layer, the photoelectric conversion layer being laminated on a surface of the light transmitting layer on a side opposite to a light incident surface and including a second compound semiconductor different from the first compound semiconductor,
the light transmitting layer includes:
a first semiconductor layer provided on the light incident surface side and having a thickness allowing transmission of the visible light; and
a second semiconductor layer configured to photoelectrically convert visible light transmitted through the first semiconductor layer, the second semiconductor being laminated on a surface of the first semiconductor layer opposite to the light incident surface, and
the second semiconductor layer has a lower impurity concentration than an impurity concentration of the first semiconductor layer and a higher impurity concentration than an impurity concentration of the photoelectric conversion layer.

2. The photodetection device according to claim 1, further comprising:
a transparent electrode disposed on the light incident surface side of the light transmitting layer and transmitting the infrared light and the visible light.

3. The photodetection device according to claim 1, further comprising:
a passivation layer disposed on the light incident surface side of the light transmitting layer and transmitting the infrared light and the visible light.

4. The photodetection device according to claim 1, further comprising:
a transparent electrode and a passivation layer that are disposed on the light incident surface side of the light transmitting layer and transmit the infrared light and the visible light.

5. The photodetection device according to claim 1, wherein
the second semiconductor layer is formed by laminating layers of a plurality of stages, and
an impurity concentration of a first stage located on the photoelectric conversion layer side among the plurality of stages is lower than an impurity concentration of a second stage laminated on the light incident surface side of the first stage.

6. The photodetection device according to claim 1, wherein
the second semiconductor layer has an impurity concentration becoming lower in gradation toward the photoelectric conversion layer side.

7. The photodetection device according to claim 1, wherein
the first semiconductor layer has a different thickness for each of the pixels.

8. The photodetection device according to claim 7, wherein
the first semiconductor layer has a thickness allowing transmission of the visible light in a first pixel among a plurality of pixels, and has a thickness that prevents transmission of the visible light in a second pixel.

9. The photodetection device according to claim 1, wherein
the light transmitting layer includes any of InP, InGaAsP, InGaAlAs, InAlAs, InAlAsSb, and AlAsSb.

10. The photodetection device according to claim 1, wherein
the photoelectric conversion layer contains any of InGaAs and InGaAs/GaAsSb.

11. The photodetection device according to claim 1, wherein
the light transmitting layer and the photoelectric conversion layer are n-type, and contain any of Si and S as an impurity.

12. The photodetection device according to claim 1, wherein
the light transmitting layer and the photoelectric conversion layer are p-type, and contain any of Mg, Cd, Al, and Zn as an impurity.

13. The photodetection device according to claim 1, wherein
the first semiconductor layer has a thickness of 5×10¹⁷ cm⁻³ or more and 30 nm or less.

14. An electronic device comprising
a photodetection device, the photodetection device comprising:
a pixel region in which a plurality of pixels is arranged in a matrix, the plurality of pixels being capable of generating electric signals in accordance with infrared light and visible light incident from outside, wherein
the pixel region includes:
a light transmitting layer including a first compound semiconductor and transmitting incident infrared light; and
a photoelectric conversion layer configured to photoelectrically convert infrared light transmitted through the light transmitting layer, the photoelectric conversion layer being laminated on a surface of the light transmitting layer on a side opposite to a light incident surface and including a second compound semiconductor different from the first compound semiconductor,
the light transmitting layer includes:
a first semiconductor layer provided on the light incident surface side and having a thickness allowing transmission of the visible light; and
a second semiconductor layer configured to photoelectrically convert visible light transmitted through the first semiconductor layer, the second semiconductor being laminated on a surface of the first semiconductor layer opposite to the light incident surface, and
the second semiconductor layer has a lower impurity concentration than an impurity concentration of the first semiconductor layer and a higher impurity concentration than an impurity concentration of the photoelectric conversion layer.
